(19) United States
(12) Patent Application Publication
(10) Pub. No.: US 2014/0083360 A1
(43) Pub. Date: Mar. 27, 2014

(54) PROCESS CHAMBER HAVING MORE UNIFORM GAS FLOW

(71) Applicant: APPLIED MATERIALS, INC., Santa Clara, CA (US)

(72) Inventors: MEHMET TUGRUL SAMIR, Mountain View, CA (US); SHU-KWAN LAU, Mountain View, CA (US)

(73) Assignee: APPLIED MATERIALS, INC., Santa Clara, CA (US)

(21) Appl. No.: 14/035,922

(22) Filed: Sep. 24, 2013

Related U.S. Application Data
(60) Provisional application No. 61/705,884, filed on Sep. 26, 2012.

(51) Int. Cl. H01L 21/02

(52) U.S. Cl. CPC H01L 21/02104
USPC 118/715; 220/212

(57) ABSTRACT

Embodiments of process chambers having flow path defining components that may provide more uniform gas flow are provided herein. In some embodiments, a process chamber lid to provide more uniform gas flow may include a dome; an outwardly extending flange disposed about a peripheral edge of the dome; and an upwardly sloped portion coupling the peripheral edge of the dome to the outwardly extending flange, wherein a portion of the outwardly extending flange and a portion of the upwardly sloped portion form a flow path with an interior surface of a process chamber when the process chamber lid is disposed atop the process chamber to provide a flow of gas towards an interior of the process chamber, wherein an angle between the upwardly sloped portion and a bottom surface of the outwardly extending flange is less than 90 degrees.

### CROSS-REFERENCE TO RELATED APPLICATIONS

This application claims benefit of U.S. provisional patent application Ser. No. 61/705,884, filed Sep. 26, 2012, which is herein incorporated by reference in its entirety.

### FIELD

Embodiments of the present invention generally relate to semiconductor processing equipment.

### BACKGROUND

Certain conventional process chambers include a process chamber lid that partially defines a lateral flow path for process gases to enter and be distributed within the process chamber. However, the inventors have observed that due to the geometry of the process chamber lid the flow of the process gases may be non-uniform. In addition, in some areas beneath the process chamber lid, circular flows of process gases may be formed. The inventors have observed that the non-uniform and/or circular flows cause an uneven distribution of process gas within the process chamber, thereby causing process non-uniformities.

Therefore, the inventors have provided embodiments of process chambers having improved flow characteristics.

### SUMMARY

Embodiments of process chambers having flow path defining components that may provide more uniform gas flow are provided herein. In some embodiments, a process chamber lid to provide more uniform gas flow may include a dome, an outwardly extending flange disposed about a peripheral edge of the dome; and an upwardly sloped portion coupling the peripheral edge of the dome to the outwardly extending flange, wherein a portion of the outwardly extending flange and a portion of the upwardly sloped portion form a flow path with an interior surface of a process chamber when the process chamber lid is disposed atop the process chamber to provide a flow of gas towards an interior of the process chamber, wherein an angle between the upwardly sloped portion and a bottom surface of the outwardly extending flange is less than 90 degrees.

In some embodiments, a process chamber may include a substrate support to support a substrate; a gas inlet port disposed proximate the substrate support; and a process chamber lid disposed opposite the substrate support. The process chamber lid may include a dome; an outwardly extending flange disposed about a peripheral edge of the dome; and an upwardly sloped portion coupling the peripheral edge of the dome to the outwardly extending flange, wherein a portion of the outwardly extending flange and a portion of the upwardly sloped portion form a flow path with an interior surface of the process chamber when the process chamber lid is disposed atop the process chamber to provide a flow of gas towards an interior of the process chamber, wherein an angle between the upwardly sloped portion and a bottom surface of the outwardly extending flange is less than 90 degrees.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a schematic view of a portion of a conventional process chamber lid.

FIG. 2 depicts a process chamber lid in accordance with some embodiments of the present invention.

FIG. 3 depicts a process chamber having a process chamber lid in accordance with some embodiments of the present invention.

FIG. 4 depicts a flow simulation in a process chamber in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of process chambers having flow path defining components that may provide more uniform gas flow are provided herein. For example, in some embodiments, process chamber lids and process chambers incorporating such process chamber lids are provided. In some embodiments, the inventive process chambers may advantageously provide a uniform flow path for process gases provided to the process chamber, thereby providing a more uniform distribution of process gases and, therefore, more uniform processing, as compared to conventionally utilized process chambers.

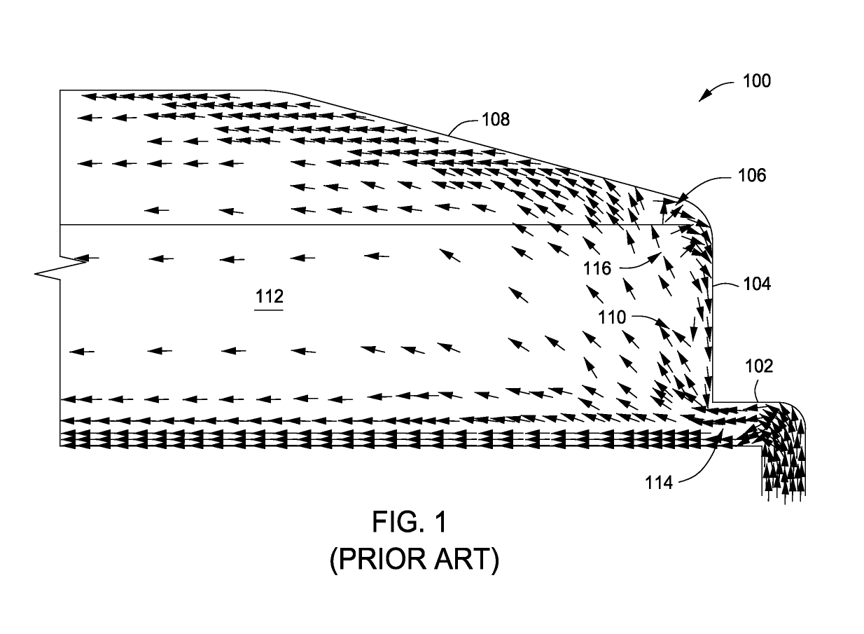

Conventionally utilized process chambers may include flow path defining components (such as a process chamber lid) that, either alone or in combination with one or more interior surfaces of the process chamber (e.g., liners, chamber walls, substrate supports, or the like), provide a flow path for process gases to enter the process chamber. For example, FIG. 1 depicts a schematic side view of a portion of a conventional process chamber lid 100. The interior profile of the process chamber lid 100 (and liner, when present) may include a geometry that has a transition 104 between a gas inlet 102 and a domed portion 108 of the process chamber lid 100 that has a substantially perpendicular orientation with respect to an opening 114 of the gas inlet 102. The inventors have observed that due to such geometry, as a process gas enters a processing volume 112 of the process chamber via the gas inlet 102 the process gas flow displays a non-uniform entry flow profile (e.g., as indicated by the flow arrows at 110) proximate the gas inlet 102 and circular flows, for example, such as eddy flows (e.g., as indicated by the flow arrows at 116) proximate top portions 106 of the process chamber lid 100. Without being limited by theory, the inventors believe that such non-uniform and/or circular flows may be caused by a variation in pressure caused by a sudden expansion of volume as the process gas flows from the opening 114 of the gas inlet 102 to the processing volume 112.

The inventors have observed that the non-uniform and/or circular flows cause an uneven distribution of process gas within the process chamber, thereby causing process non-uniformities. In addition, the circular flows may trap components of the process gas (e.g., precursors) proximate portions of the process chamber lid 100, causing high concentrations of the process gas components in those portions of the process chamber. In addition, the circular flows may trap cleaning gases proximate portions of the process chamber lid 100, causing those portions of the process chamber to remain dirty after cleaning processes are performed. In some instances the local concentration of the process gas components may be high enough to cause gas-phase decomposition, thereby creating particles that may be transported throughout the process chamber. Such particles may undesirably deposit atop process chamber and/or substrate surfaces.

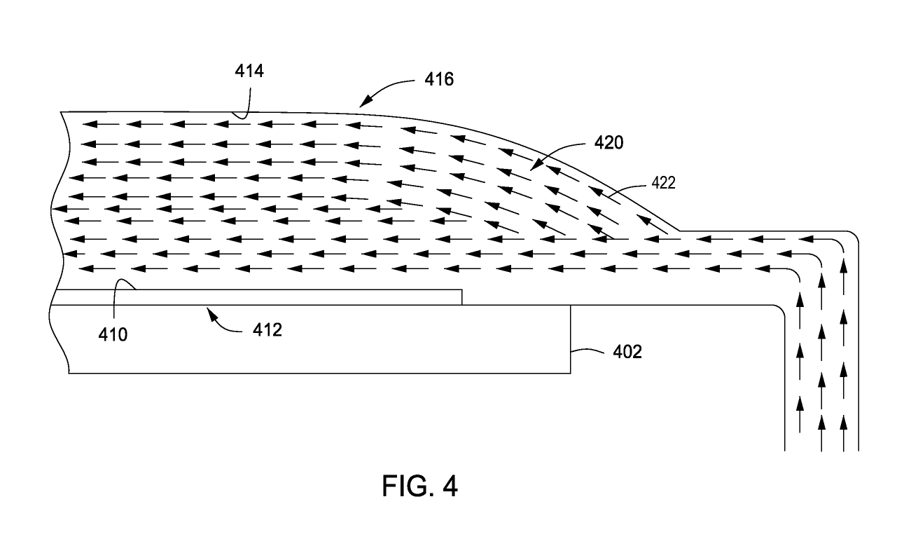

Accordingly, the inventors have provided embodiments of process chambers that advantageously provide more uniform gas flow within the process chamber, for example, such as the gas flow depicted in FIG. 4. In some embodiments, the flow field 420 may advantageously comprise laminar streamlines 422 (indicated by arrows) that do not separate from the boundaries or surfaces, (e.g., an inner surface 414 of the lid 416, a top surface 410 of the substrate 412 disposed on a substrate support 402, or the like) of the flow path. For example, in some embodiments, the laminar streamlines 422 of the flow field 420 may not separate from at least one of the inner surface 414 of the lid 416 or the top surface 410 of the substrate 412, such as shown in FIG. 4. In some embodiments, the laminar streamlines 422 may be substantially parallel in an area proximate the substrate 412. The more uniform gas flow may further reduce or eliminate the above-described eddy currents, thereby improving processing uniformity and reducing the risk or incidence of substrate or chamber contamination due to particles from deposited materials.

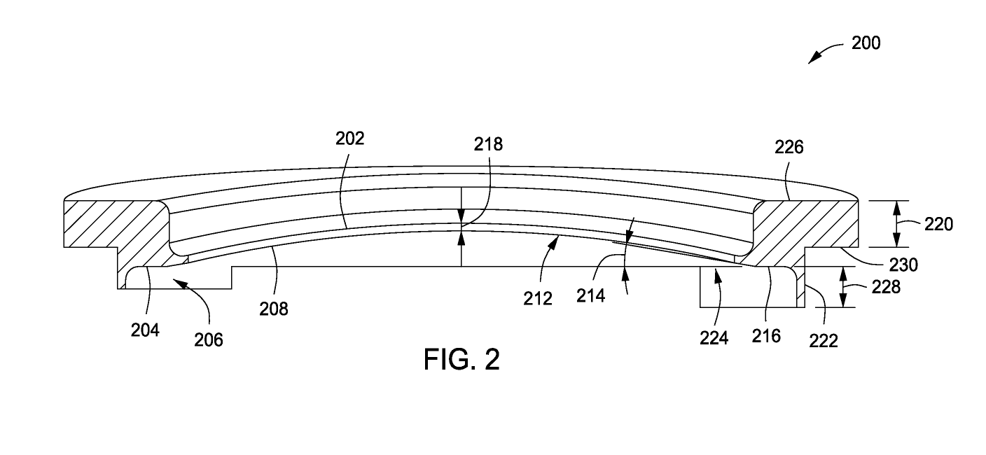

The process chamber may be configured in any manner suitable to provide the above described uniform gas flow within the process chamber. For example, the position or shape of gas inlets, substrate support, chamber body, chamber lid (e.g., such as described below with respect to FIG. 2), or the like may be configured to provide a desired flow path across the surface of the substrate.

FIG. 2 depicts a non-limiting example of a process chamber lid 200 that defines a portion of a flow path in a process chamber in accordance with some embodiments of the present invention. Although described in terms of a particular process chamber lid in FIG. 2, different lid configurations and other process chamber components may be provided to assist in the definition of the flow path as disclosed herein. In some embodiments, the process chamber lid 200 may generally comprise a dome 202 and an outwardly extending flange 204 disposed about a peripheral edge 206 of the dome 202. An upwardly sloped portion 208 of the dome 202 couples the dome 202 to the outwardly extending flange 204, as shown in FIG. 2. In some embodiments, the upwardly sloped portion 208 is not vertical, or perpendicular to the general plane of the chamber lid 200. The dome 202 may have any thickness 218 suitable to provide structural integrity for the processes to be performed in the process chamber, for example, such as about 4 to about 10 mm, or in some embodiments, about 6 mm.

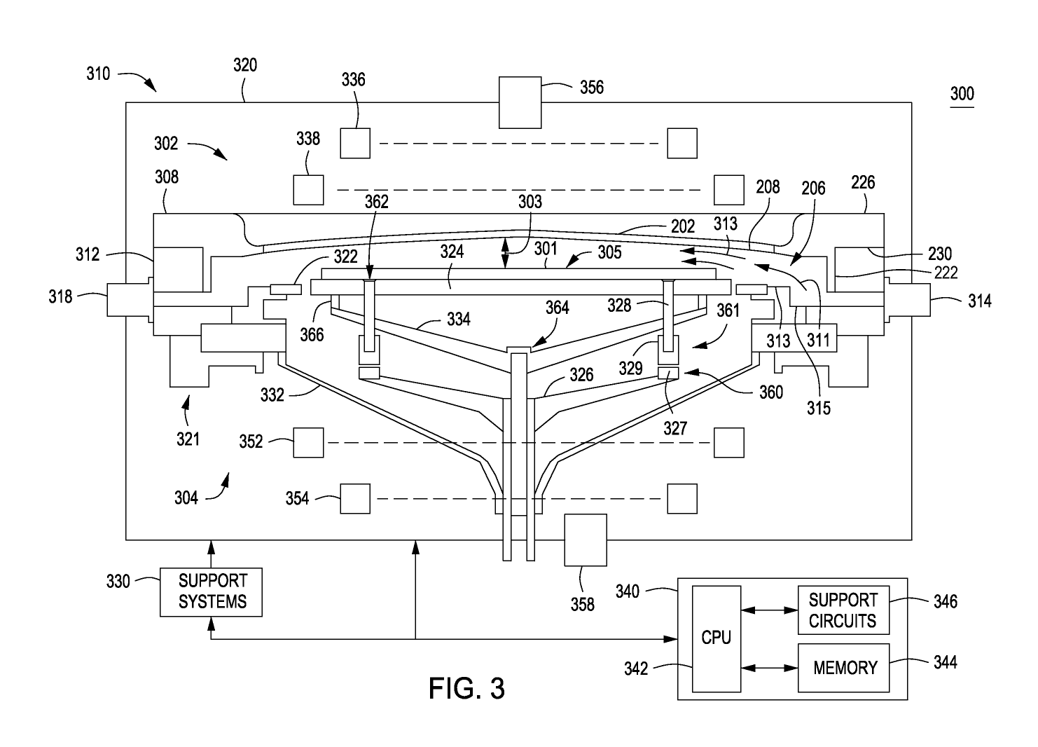

When the chamber lid 200 is disposed atop a process chamber, a flow path is defined between the upwardly sloped portion 208 of the dome 202 and one or more interior surfaces of the process chamber (e.g., surfaces 313, 315 of the process chamber 300, for example, such as shown in FIG. 3). The inventors have observed that by providing the upwardly sloped portion 208 between the dome 202 and the outwardly extending flange 204 the a more laminar flow path of the process gases may be provided, for example, having laminar streamlines along a substrate disposed opposite the dome 202 and along an inner surface 212 of the dome 202 that are absent of circular flows (e.g., such as the circular flows shown in FIG. 1). Providing a uniform flow of gases and eliminating circular flows, advantageously reduces the instances of particle formation within the process chamber and provides a more uniform distribution of process gases within the process chamber, thereby increasing process uniformity.

In some embodiments, the upwardly sloped portion 208 may be configured such that an angle 214 between the upwardly sloped portion 208 and a bottom surface 216 of the outwardly extending flange 204 may be any angle suitable to provide the uniform flow of gas described above. For example, in some embodiments, the angle may be less than 90 degrees, or in some embodiments, between about 0 and about 30 degrees.

The process chamber lid 200 may be fabricated from any process compatible material, for example, such as quartz (SiO₂). For example, in some embodiments, the dome 202 may be fabricated from a transparent quartz and the outwardly extending flange 204 fabricated from opaque quartz. In such embodiments, a transitional portion 224 of quartz may be disposed between the dome 202 and the outwardly extending flange 204. The transitional portion 224 may provide a transparency gradient along the transitional portion 224 that increases in transparency from the outwardly extending flange 204 to the dome 202.

In some embodiments, the process chamber lid 200 may comprise a bottom ring 222 coupled to the bottom surface 216 of the outwardly extending flange 204. The bottom ring 222 may be fabricated from any process compatible material, for example, such as quartz. When present, the bottom ring 222 may be configured to cover one or more interior surfaces of the process chamber when the process chamber lid 200 is disposed on the process chamber, thereby functioning as an integrated liner and eliminating the need for one or more separate liners within the process chamber. Providing an integral process chamber lid and liner reduces the amount of separate components within the process chamber, thereby advantageously reducing the overall cost of the process chamber and making the process chamber easier to maintain.

In addition, eliminating one or more liners from the process chamber reduces the amount of thermally floating parts (e.g., liners within the process chamber), thereby advantageously increasing process repeatability. The bottom ring 222 may have any thickness 228 suitable to function as described above. For example, in some embodiments, the bottom ring 222 may have a thickness of about 2 to about 10 mm.

In some embodiments, the process chamber lid 200 may comprise a top ring 226 coupled to a top of the outwardly extending flange 204. In some embodiments, the top ring 226 may have a bottom surface 230 configured to interface with one or more interior surfaces of the process chamber to facilitate installation of the process chamber lid 200 on the process chamber. The top ring 226 may be fabricated from any process compatible material, for example, such as quartz. The top ring 226 may have any thickness 220 suitable to facilitate installation of the process chamber lid 200 and support the process chamber lid 200 when installed in the process chamber. For example, in some embodiments, the top ring 226 may comprise a thickness 220 of about 10 to about 50 mm.

Although described as separate components, the dome 202, outwardly extending flange 204, bottom ring 222 and top ring 226 may be fabricated from a single piece of material (e.g., quartz) thereby providing a unitary design. Providing a unitary design allows for the complete replacement of the process chamber lid 200 when needed, thereby advantageously simplifying maintenance of the process chamber.

Although the process chamber lid 200 is described as generally comprising a dome 202, the process chamber lid 200 may comprise any shape suitable to provide the desired uniform gas flow described above. For example, the process chamber lid 200 may have at least portions that are substantially parallel with a lower boundary of the flow path (e.g., the top surface 305 of the substrate 301).

The improved flow path, for example as provided by the process chamber lid 200, disclosed herein may be utilized in any suitable process chamber where process gases are provided from a side of the process chamber and flow across the lid. Examples of suitable semiconductor process chambers include, but are not limited to, those adapted for performing epitaxial deposition processes, for example epitaxial silicon deposition processes, such as the RP EPI reactor, available from Applied Materials, Inc. of Santa Clara, Calif. Other process chambers, including those configured to perform other processes, may also benefit from modification in accordance with the teachings provided herein.

An exemplary process chamber is described below with respect to FIG. 3, which depicts a schematic, cross-sectional view of a semiconductor substrate process chamber 300 suitable for use with the process chamber lid 200 as described above. The process chamber 300 may be adapted for performing epitaxial deposition processes, such as epitaxial silicon deposition, and illustratively comprises a chamber body 310, support systems 330, and a controller 340.

The chamber body 310 generally includes an upper portion 302, a lower portion 304, and an enclosure 320. The upper portion 302 is disposed on the lower portion 304 and includes the process chamber lid 200, a clamp ring 308, a baseplate 312, one or more upper lamps 336 and one or more lower lamps 352, and an upper pyrometer 356. In some embodiments, the process chamber lid 200 is disposed atop the process chamber 300 such that the bottom surface 230 of the top ring 226 rests atop the baseplate 312. In such embodiments, the bottom ring 222 covers at least a portion of the baseplate 312. In some embodiments, a distance 303 between the dome 202 of the process chamber lid 200 and a top surface 305 of the substrate 301 may be about 20 mm to about 60 mm, or in some embodiments, about 40 mm.

The lower portion 304 is coupled to a process gas intake port 314 and an exhaust port 318 and comprises a baseplate assembly 321, a lower dome 332, a substrate support 324, a pre-heat ring 322, a substrate lift assembly 360, a substrate support assembly 364, one or more upper lamps 338 and one or more lower lamps 354, and a lower pyrometer 358. Although the term “ring” is used to describe certain components of the process chamber 300, such as the pre-heat ring 322, it is contemplated that the shape of these components need not be circular and may include any shape, including but not limited to, rectangles, polygons, ovals, and the like.

When the chamber lid 200 is disposed atop the process chamber 300, a flow path 311 is defined between the upwardly sloped portion 208 of the dome 202 and one or more interior surfaces of the process chamber (e.g., surfaces 313, 315 of the process chamber 300). The chamber lid 200 advantageously causes the flow path 311 of the process gases to be more uniform and to have laminar streamlines along the substrate 301 and along the dome 202. In addition, the flow path 311 may further advantageously be free of any circular flows (e.g., such as the circular flows shown in FIG. 1).

During processing, the substrate 301 is disposed on the substrate support 324. The lamps 336, 338, 352, and 354 are sources of infrared (IR) radiation (i.e., heat) and, in operation, generate a pre-determined temperature distribution across the substrate 301. In some embodiments, the lid 306, the clamp ring 308, and the lower dome 332 are formed from quartz; however, other IR-transparent and process compatible materials may also be used to form these components.

The substrate support assembly 364 generally includes a support bracket 334 having a plurality of support pins 366 coupled to the substrate support 324. The substrate lift assembly 360 comprises a substrate lift shaft 326 and a plurality of lift pin modules 361 selectively resting on respective pads 327 of the substrate lift shaft 326. The lift pins 328 are movably disposed through openings 362 in the substrate support 324. In operation, the substrate lift shaft 326 is moved to engage the lift pins 328. When engaged, the lift pins 328 may raise the substrate 301 above the substrate support 324 or lower the substrate 325 onto the substrate support 324.

The support systems 330 include components used to execute and monitor pre-determined processes (e.g., growing epitaxial silicon films) in the process chamber 300. Such components generally include various sub-systems. (e.g., gas panel(s), gas distribution conduits, vacuum and exhaust sub-systems, and the like) and devices (e.g., power supplies, process control instruments, and the like) of the process chamber 300. These components are well known to those skilled in the art and are omitted from the drawings for clarity.

The controller 340 generally comprises a central processing unit (CPU) 342, a memory 344, and support circuits 346 and is coupled to and controls the process chamber 300 and support systems 330, directly (as shown in FIG. 3) or, alternatively, via computers (or controllers) associated with the process chamber and/or the support systems.

Thus, embodiments of process chambers having flow path defining components that may provide more uniform gas flow have been disclosed. In some embodiments, process chamber lids and process chambers incorporating such process chamber lids are provided that may advantageously provide a more uniform flow path for process gases provided to the process chamber, thereby providing a more uniform distribution of process gases and, therefore, more uniform processing, as compared to conventionally utilized process chambers.

While the foregoing is directed to embodiments of the present invention, other and further embodiments of the invention may be devised without departing from the basic scope thereof.

1. A process chamber lid to provide more uniform gas flow, comprising:
a dome;
an outwardly extending flange disposed about a peripheral edge of the dome; and
an upwardly sloped portion coupling the peripheral edge of the dome to the outwardly extending flange, wherein a portion of the outwardly extending flange and a portion of the upwardly sloped portion form a flow path with an interior surface of a process chamber when the process chamber lid is disposed atop the process chamber to provide a flow of gas toward an interior of the process chamber, wherein an angle between the upwardly sloped portion and a bottom surface of the outwardly extending flange is less than 90 degrees.

2. The process chamber lid of claim 1, wherein the bottom surface of the outwardly extending flange is substantially horizontal and wherein the angle between the upwardly sloped portion and the bottom surface of the outwardly extending flange is up to about 30 degrees.

3. The process chamber lid of claim 1, wherein the process chamber lid is fabricated from quartz.

4. The process chamber lid of claim 1, wherein the outwardly extending flange is fabricated from an opaque quartz and the dome is fabricated from a transparent quartz.

5. The process chamber lid of claim 4, further comprising:
a transitional portion of quartz disposed between the dome and the outwardly extending flange, wherein the transitional portion has a transparency gradient along the transitional portion that increases in transparency from the outwardly extending flange to the dome.

6. The process chamber lid of claim 1, wherein the process chamber is configured to perform an epitaxial deposition process.

7. The process chamber lid of claim 1, further comprising:
a bottom ring coupled to the bottom surface of the outwardly extending flange, the ring extending downward from the outwardly extending flange to cover an interior surface of the process chamber when the process chamber lid is disposed atop the process chamber.

8. The process chamber lid of claim 1, further comprising:
a top ring coupled to a top of the outwardly extending flange, the top ring having a bottom surface to interface with an interior surface of the process chamber when the process chamber lid is disposed atop the process chamber.

9. The process chamber lid of claim 1, wherein the dome is about 4 mm to about 10 mm thick.

10. The process chamber lid of claim 1, wherein a distance between an inner surface of the dome and a top surface of a substrate disposed on a substrate support within the process chamber is about 20 mm to about 60 mm.

11. A process chamber, comprising:
a substrate support to support a substrate;
a gas inlet port disposed proximate the substrate support; and
a process chamber lid disposed opposite the substrate support, the process chamber lid comprising:
a dome;
an outwardly extending flange disposed about a peripheral edge of the dome; and
an upwardly sloped portion coupling the peripheral edge of the dome to the outwardly extending flange, wherein a portion of the outwardly extending flange and a portion of the upwardly sloped portion form a flow path with an interior surface of the process chamber when the process chamber lid is disposed atop the process chamber to provide a flow of gas towards an interior of the process chamber, wherein an angle between the upwardly sloped portion and a bottom surface of the outwardly extending flange is less than 90 degrees.

12. The process chamber of claim 11, wherein the bottom surface of the outwardly extending flange is substantially horizontal and wherein the angle between the upwardly sloped portion and the bottom surface of the outwardly extending flange is about 0 degrees to about 30 degrees.

13. The process chamber of claim 11, wherein the process chamber lid is fabricated from quartz.

14. The process chamber of claim 11, wherein the outwardly extending flange is fabricated from an opaque quartz and the dome is fabricated from a transparent quartz.

15. The process chamber of claim 14, further comprising:
a transitional portion of quartz disposed between the dome and the outwardly extending flange, wherein the transitional portion has a transparency gradient along the transitional portion that increases in transparency from the outwardly extending flange to the dome.

16. The process chamber of claim 11, wherein the process chamber is configured to perform an epitaxial deposition process.

17. The process chamber of claim 11, further comprising:
a bottom ring coupled to the bottom surface of the outwardly extending flange, the ring extending downward from the outwardly extending flange to cover an interior surface of the process chamber when the process chamber lid is disposed atop the process chamber.

18. The process chamber of claim 11, further comprising:
a top ring coupled to a top of the outwardly extending flange, the top ring having a bottom surface to interface with an interior surface of the process chamber when the process chamber lid is disposed atop the process chamber.

19. The process chamber of claim 11, wherein the dome is about 4 mm to about 10 mm thick.

20. The process chamber of claim 11, wherein a distance between an inner surface of the dome and a top surface of a substrate disposed on a substrate support within the process chamber is about 20 mm to about 60 mm.
